(19) United States
(12) Patent Application Publication
(10) Pub. No.: US 2009/0085204 A1
(43) Pub. Date: Apr. 2, 2009

(54) Wafer-level package and method of manufacturing the same

(75) Inventors: Seung Wook Park, Suwon-si (KR); Chun Choi, Suwon-si (KR); Ju Pyo Hong, Suwon-si (KR); Si Joong Yang, Suwon-si (KR); Dae Jun Kim, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/216,630

(22) Filed: Jul. 8, 2008

(30) Foreign Application Priority Data
Sep. 28, 2007 (KR) 10-2007-0098168

(51) Int. Cl. H01L 21/56; H01L 23/498

(52) U.S. Cl. 257/737; 438/124; 257/E23.068; 257/E21.502

(57) ABSTRACT

Provided is a wafer-level package including a wafer-level semiconductor chip having a plurality of integrated circuits (ICs) and pads formed on the top surface thereof; a molding material of which the outer portion is supported by the top surface of the semiconductor chip such that a cavity is provided on the semiconductor chip; and a conducive member filled in a plurality of vias which are formed in arbitrary positions of the molding material so as to pass through the molding material, the conductive member being connected to the pads.

### CROSS-REFERENCE TO RELATED APPLICATIONS

This application claims the benefit of Korean Patent Application No. 10-2007-0098168 filed with the Korea Intellectual Property Office on Sep. 28, 2007, the disclosure of which is incorporated herein by reference.

### BACKGROUND OF THE INVENTION

1. Field of the Invention

The present invention relates to a wafer-level package and a method of manufacturing the same.

2. Description of the Related Art

One of main trends in a semiconductor industry is to reduce the size of semiconductor elements. In particular, a demand for the reduction in size increases in a semiconductor chip package industry. The package is formed by sealing an integrated circuit (IC) chip using plastic or ceramic resin such that the IC chip can be installed in an actual electronic device.

A conventional typical package is much large than an IC chip installed therein. Accordingly, package engineers have attempted to reduce a package size to about a chip size.

Owing to the above attempts, a chip-scale package (CSP) and a wafer-level chip-scale package (WLCSP) have been recently developed. The chip-scale package is also call ‘chip-size package’. In a conventional package manufacturing method, package assembly is performed on a separate package basis. On the other hand, in the WLCSP method, a plurality of packages are simultaneously assembled and manufactured at a wafer level.

Development of semiconductor IC chips has contributed to development of package technologies, leading to the high-density, high-speed, miniaturization and slimness of the package. The structure of a package device has evolved from a pin insert type or a through hole mount type to a surface mount type, thereby increasing the mount density for a circuit board. Recently, researches are actively conducted on a chip-size package that can reduce a package size to about a chip size while maintaining bare chip characteristics in a package state.

A WLCSP is one of chip-size packages. In the WLCSP, chip pads are rerouted or redistributed on a chip surface, and solder balls are then formed. In the WLCSP, a chip or a die is directly mounted on a circuit board by using a flip-chip method, and solder balls formed on the redistributed circuit of the chip are bonded to conductive pads of the circuit board. At this point, solder balls are also formed on the conductive pads and are thus bonded to the solder balls of the package.

Recently, there have been introduced a variety of CSP technologies that can reduce a package size to about a semiconductor chip size. These technologies are rapidly spread thanks to the miniaturization and high-integration of semiconductor devices.

A wafer-level package (WLP) technology is esteemed as the next-generation CSP technology. In the WLP technology, the entire assembly process is completed in a wafer level where chips are not diced. In the WLP technology, a series of assembly processes, such as die bonding, wire bonding, and molding, are completed in a wafer state where a plurality of chips are connected to one another, and then the resulting structure is diced to manufacture the complete products.

Therefore, compared to the CSP technology, the WLP technology can further reduce the total package costs.

In general, solder balls are formed on an active side of a semiconductor chip in the WLCSP. This structure makes it difficult to stack the WLCSP or to apply the WLCSP to the manufacturing of a sensor package such as a charge coupled device (CCD).

A conventional packaged IC device, which includes an image sensor package manufactured using the WLCSP technology, is disclosed in Korean Patent Publication No. 2002-74158. The structure of the conventional packaged IC device will be briefly described with reference to FIG. 1.

FIG. 1 illustrates an IC device provided with a microlens array 100 formed on a crystal substrate.

Referring to FIG. 1, a microlens array 100 is formed on the top surface of a crystal substrate 102. A package layer 106, which is generally formed of glass, is hermetically attached onto the bottom surface of the crystal substrate 102 through an epoxy 104. An electrical contact 108 is formed along each edge of the package layer 106. A solder ball bump 110 is formed on the bottom surface of the package layer 106, and a conductive pad 112 is formed on the top surface of the crystal substrate 102. The electrical contact 108 is connected to the solder ball bump 110 and is electrically connected to the conductive pad 112.

A package layer 114, which is generally formed of glass, and an associated spacer member 116 are hermetically attached onto the top of the crystal substrate 102 by an adhesive such as an epoxy 108 such that a cavity 120 can be formed between the microlens array 100 and the package layer 114.

The electrical contact 108 is formed, for example by plating, on the slant surfaces of the epoxy 104 and the package layer 106.

In the conventional IC device, however, the electrical contact 108 is formed to electrically connect the conductive pad 112 of the crystal substrate 102 to the bump 110. Since the IC device is manufactured through the process where the plurality of components are stacked, the structure and process of the IC device becomes complicated.

To solve such a problem, an IC device is developed, in which the microlens array 100 is provided on the crystal substrate 102 which is formed in a rectangular shape so as to connect the conductive pad 112 and the bump 110, the conductive pad 112 and the bump 110 are electrically connected through a via (not shown) which passes through the crystal substrate 102, and the package layer 114 formed of glass is installed on the crystal substrate 102 through the spacer member 116 and an adhesive such as epoxy 118 such that the entire top surface of the crystal substrate 102 is sealed.

In the IC device constructed in such a manner, however, the entire top surface of the crystal substrate 102 is covered and sealed by the package layer 114 formed of glass. Therefore, a drilling process for forming a via and a subsequent process cannot be performed using the top surface of the crystal substrate 102, but should be performed using only the bottom surface of the crystal substrate 102. Therefore, there are difficulties in performing the process.

Further, a plurality of package layers using a substrate should be formed, and such a material as gold is used to electrically connect the conductive pad 112 to the bump 110. Thus, a manufacturing cost increases.

FIG. 2 is a diagram showing another IC device using a CSP scheme. As shown in FIG. 2, a semiconductor chip 210 having a plurality of ICs 211 formed thereon are mounted on a substrate 201 having an electrode 202 formed therein such that a cavity 230 with a height corresponding to the height of a solder bump 220 is provided therebetween. Further, a molding material 240 formed of resin is molded on the outer surface of the semiconductor chip 210. Then, the manufacturing of the package is completed.

In such a package manufacturing method, the outer surface of the semiconductor chip 210 coupled to the top surface of the substrate 201 should be sealed using the molding material 240, and the electrode 202 for electrically connecting the semiconductor chip 210 is formed in a complex shape. Therefore, a manufacturing cost increases, and there are difficulties in reducing the thickness of the package.

### SUMMARY OF THE INVENTION

An advantage of the present invention is that it provides a wafer-level package, in which a molding material is directly attached to the top surface of a semiconductor chip having a plurality of integrated circuits (ICs) and pads formed thereon such that a cavity is provided therebetween. Therefore, a manufacturing process of the wafer-level package is simplified so that productivity is enhanced, and the manufacturing of the package can be performed without a separate substrate.

Another advantage of the invention is that it provides a method of manufacturing a wafer-level package.

Additional aspects and advantages of the present general inventive concept will be set forth in part in the description which follows and, in part, will be obvious from the description, or may be learned by practice of the general inventive concept.

According to an aspect of the invention, a wafer-level package comprises a wafer-level semiconductor chip having a plurality of integrated circuits (ICs) and pads formed on the top surface thereof; a molding material of which the outer portion is supported by the top surface of the semiconductor chip such that a cavity is provided on the semiconductor chip; and a conducive member filled in a plurality of vias which are formed in arbitrary positions of the molding material so as to pass through the molding material, the conductive member being connected to the pads.

Each of the pads may be formed of a bump. Further, the conductive member may be formed of any one of a wire, a bump, and a conductive filler.

The vias may be formed by a drilling process using a saw or irradiation of laser. Further, the vias are formed in positions corresponding to the respective pads formed on the semiconductor chip.

The conductive member filled in each of the vias may be composed of a conductive filler such as metal or conductive polymer. Further, the conductive member may be formed so as to project from the top surface of the molding material or may be formed with the same height as the molding material.

The molding material may be formed of transparent thermosetting resin such as epoxy, polymer, PR (photoresist) or PI (polyimide). Further, the outer portion of the molding material is closely fixed to the top surface of the semiconductor chip through an adhesive.

According to another aspect of the invention, a method of manufacturing a wafer-level package comprises the steps of: forming a plurality of ICs and pads on the top surface of a wafer-level semiconductor chip; molding a molding material having a groove formed in the central portion thereof; bonding and fixing the molding material to the top surface of the semiconductor chip such that a cavity is formed therebetween; forming a plurality of vias in arbitrary positions of the molding material; and filling a conductive filler into each of the vias so as to form a conductive member.

The conductive member may be formed of any one of a wire, a bump, and a conductive filler. Further, the filler filled into the via may be composed of a conductive material such as metal or conductive polymer.

The vias may be formed by a drilling process using a saw or irradiation of laser. Further, the vias are formed in positions corresponding to the respective pads formed on the semiconductor chip.

The molding material may be formed of transparent thermosetting resin such as epoxy, polymer, PR or PI.

According to a further aspect of the invention, a method of manufacturing a wafer-level package comprises the steps of: forming a plurality of ICs and pads on the top surface of a wafer-level semiconductor chip; preparing a support wafer; forming a plurality of bumps in arbitrary positions of the top surface of the support wafer; molding a molding material such that the bumps formed on the top surface of the support wafer are included; forming a groove in the central portion of the molding material; removing the support wafer; and closely coupling the molding material having the groove to the top surface of the semiconductor chip.

The groove may be formed by an etching process. Further, when the molding material is closely coupled to the top surface of the semiconductor chip, the groove and the bump exposed from the groove are caused to face the top surface of the semiconductor chip such that the groove serves as a cavity.

The molding material may be formed of transparent thermosetting resin such as epoxy, polymer, PR or PI.

Each of the bumps may be formed by a plating method such as an electroplating method or electroless plating method or may be formed of a stud bump through a bumping process. Further, the bump is formed in a position corresponding to each of the pads formed on the semiconductor chip.

The outer portion of the molding material may be closely fixed to the top surface of the semiconductor chip through an adhesive.

According to a still further aspect of the invention, a method of manufacturing a wafer-level package comprises the steps of: forming a plurality of ICs and pads on the top surface of a wafer-level semiconductor chip; forming a photosensitive layer on the top surface of the semiconductor chip such that the ICs and the pads are covered by the photosensitive layer; patterning a portion of the photosensitive layer such that the pads are exposed; forming a plurality of bumps on the top surfaces of the exposed pads; forming a primary molding material on the top surface of the photosensitive layer such that the bumps are covered; removing the photosensitive layer such that a cavity is formed around the ICs and the pads; forming a secondary molding material around the primary molding material; and thinning upper portions of the primary and secondary molding materials such that the top surfaces of the bumps are exposed.

The patterning of the photosensitive layer may be performed by an etching process. Further, the photosensitive layer may be formed of a photoresist (PR) layer coated with photosensitive liquid or a dry film resist (DFR) layer using a dry film. Furthermore, the photosensitive layer may be removed by an ashing process such as a dry or wet etching process or ion injection, or may be removed by jetting high-pressure etching liquid to fuse only the photosensitive layer, after the primary molding material is molded.

The primary and secondary molding materials formed on the semiconductor chip may be formed of transparent thermosetting resin such as epoxy, polymer, PR or PI.

Each of the bumps may be formed by a plating method such as an electroplating method or electroless plating method or may be formed of a stud bump through a bumping process. Further, the outer portion of the molding material is closely fixed to the outer portion of the top surface of the semiconductor chip through an adhesive.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 illustrates an IC device provided with a microlens array formed on a crystal substrate;

FIG. 2 is a diagram showing another IC device using a CSP scheme;

FIG. 3 is a cross-sectional view of a wafer-level package according to the invention;

FIGS. 4 to 6 are process diagrams showing a method of manufacturing a wafer-level package according to a first embodiment of the invention;

FIGS. 7 to 12 are process diagrams showing a method of manufacturing a wafer-level package according to a second embodiment of the invention;

FIG. 13 is a cross-sectional view of another example of a molding material which is applied to the second embodiment of the invention; and

FIGS. 14 to 21 are process diagrams sequentially showing a method of manufacturing a wafer-level package according to a third embodiment of the invention.

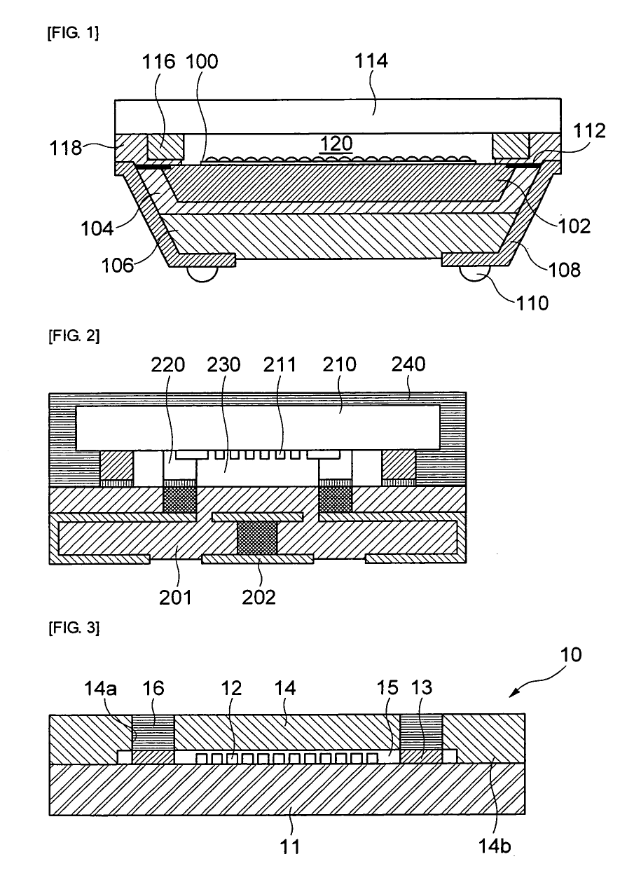

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, embodiments of the present invention will be described in detail with reference to the accompanying drawings.

Structure of Wafer-Level Package

FIG. 3 is a cross-sectional view of a wafer-level package according to the invention.

As shown in FIG. 3, the wafer-level package 10 according to the invention includes a wafer-level semiconductor chip 11 and a molding material 14 which is formed to cover the top surface of the semiconductor chip 11 such that a cavity 15 is formed therebetween.

The semiconductor chip 11 has a plurality of integrated circuits (IC) 12 formed on the center of the top surface thereof and a plurality of pads 13 mounted around the ICs 12. Further, a support portion 14b of the molding material 14 is positioned outside the pads 13, and the bottom surface of the support portion 14b is contacted with and supported by the top surface of the semiconductor chip 11.

At this time, each of the pads 13 may be formed of a general-size pad or extended pad. Alternately, the pad 13 may be constructed in the form of a bump.

The molding material 14 has a groove formed therein such that the cavity 15 can be provided when the top surface of the semiconductor chip 11 is covered by the molding material 14. The molding material 14 has a plurality of vias 14a formed in arbitrary positions thereof by a drilling process or irradiation of laser such that the vias 14a pass through the molding material 14.

Preferably, the vias 14a are formed right above the respective pads 13 formed on the top surface of the semiconductor chip 11. Inside each of the vias 14a, a conductive filler is filled so as to serve as a conductive member 16.

As a lower end of the conductive member 16 is contacted with the pad 13, the conductive member 16 and the pad 13 are electrically connected to each other. In addition to the filling of the filler, the electrical connection with the pad 13 may be achieved by a wire bonding method. Alternately, the conductive member 16 may be directly connected to the pad 13 through a bump.

The conductive filler is composed of metal or conductive polymer. Preferably, the filling height of the conductive filler is set in such a manner that the conductive member 16 projects from the top surface of the molding material 14, or is set to the same height as that of the molding material 14.

The molding material 14 is molded by a separate mold such that the groove is formed in the central portion thereof. Further, the molding material 14 is formed of transparent thermosetting resin such as epoxy, polymer, PR (photoresist) or PI (polyimide).

Between the lower end of the support portion 14b, formed on the outer portion of the molding material 14, and the outer portion of the top surface of the semiconductor chip 11, an adhesive (not shown) is interposed in such a manner that the molding material 14 and the semiconductor chip 11 is bonded and fixed to each other.

Now, a method of manufacturing the wafer-level package according to the invention will be described with the accompanying drawings.

Method of Manufacturing Wafer-Level Package

### First Embodiment

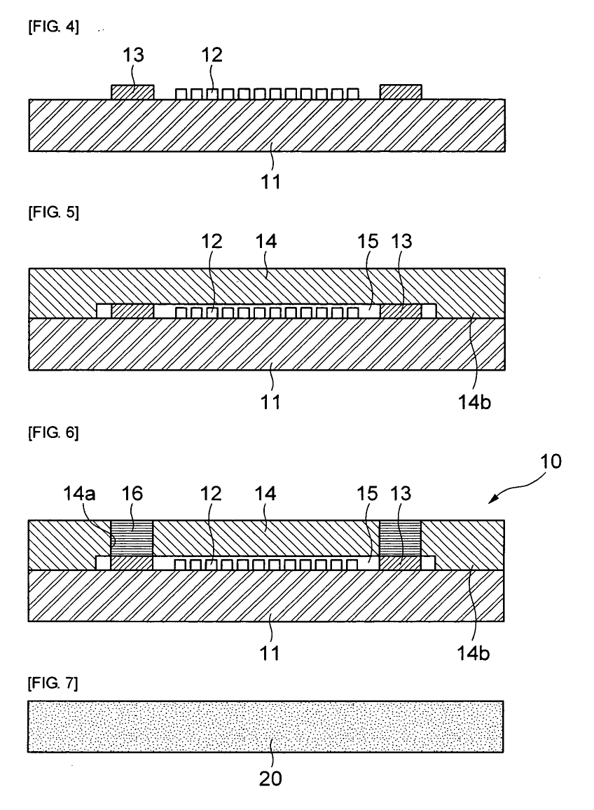

FIGS. 4 to 6 are process diagrams showing a method of manufacturing a wafer-level package according to a first embodiment of the invention.

First, as shown in FIG. 4, a wafer-level semiconductor chip 11 having a plurality of ICs 12 and pads 13 formed thereon is prepared. The semiconductor chip 11 may be formed of a microelectromechanical systems (MEMS) element or an IC element, and the plurality of pads 13 are mounted around the ICs 12 formed in the center of the top surface of the semiconductor chip 11.

Here, the pads 13 may be constructed in the form of bump.

Next, when a molding material for covering the top surface of the semiconductor chip 11 is molded, a separate mold with a predetermined shape is used to mold the molding material 14 having a groove formed in the central portion thereof.

Preferably, the molding material 14 is formed of transparent thermosetting resin such as epoxy, polymer, PR or PI.

As shown in FIG. 5, the groove of the molding material 14 is formed in a concave shape. The groove is formed with such a size as to include the ICs 12 and the pads 13 formed on the top surface of the semiconductor chip 11.

Next, the molding material 14 having the groove therein is bonded and fixed to the top surface of the wafer-level semiconductor chip 11. At this time, as the molding material 14 is closely fixed to the top surface of the semiconductor chip 11 such that the groove faces downward, a cavity 15 is formed between the semiconductor chip 11 and the molding material 14.

Further, a support portion 14b formed in the outer portion of the molding material 14 is attached to the top surface of the semiconductor chip 11 through an adhesive (not shown) coated on the lower end surface of the support portion 14b. Therefore, as the adhesive is solidified, the semiconductor chip 11 and the molding material 14 are reliably coupled to each other.

When the bonding between the semiconductor chip 11 and the molding material 14 is completed, a plurality of vias 14a are formed in arbitrary positions of the molding material 14.

The vias 14a are formed by a drilling process using a saw or irradiation of laser so as to pass through the molding material 14. Preferably, the vias 14a are formed right above the pads 13 mounted on the semiconductor chip 11.

Subsequently, a filler 16 composed of metal or conductive polymer is filled into each of the vias 14a formed in the molding material 14. In this case, the filler 16 is injected so as to come in contact with the top surface of each of the pads 13. Accordingly, as the filler 16 and the pad 13 are electrically connected to each other, the filler 16 serves as an electrode.

Preferably, the filling height of the conductive filler is set in such a manner that the conductive member 16 projects from the top surface of the molding material 14, or is set to the same height as that of the molding material 14.

### Second Embodiment

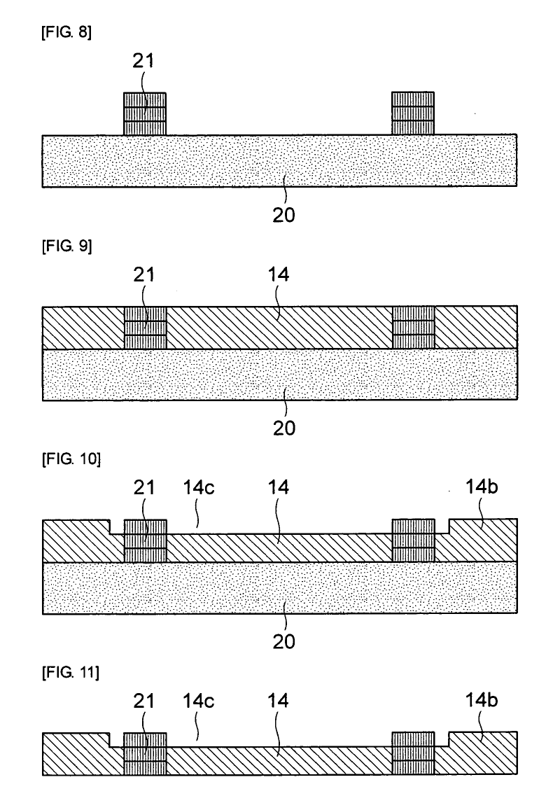

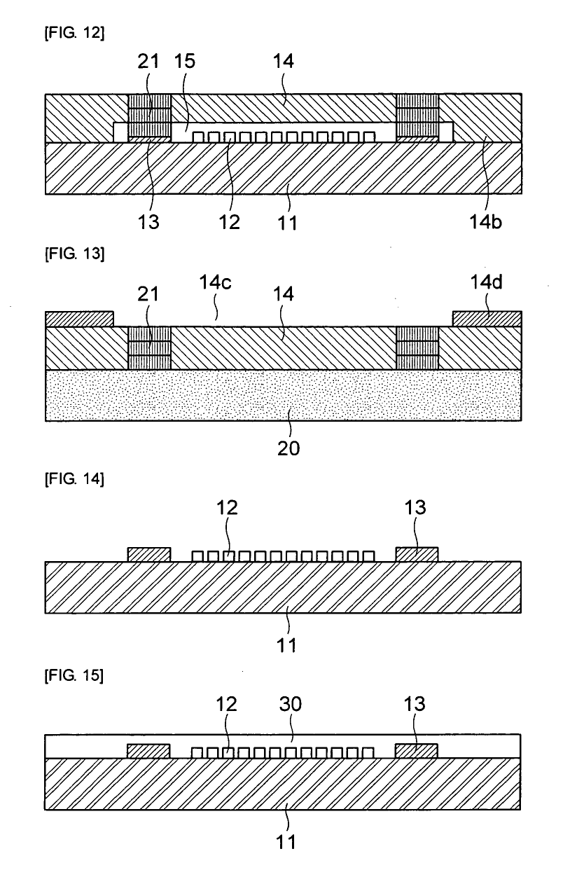

FIGS. 7 to 12 are process diagrams showing a method of manufacturing a wafer-level package according to a second embodiment of the invention.

First, a wafer-level semiconductor chip 11 having a plurality of ICs 12 and pads 13 formed thereon is prepared. The semiconductor chip 11 may be formed of a MEMS element or an IC element, and the plurality of pads 13 are mounted around the ICs 12.

Here, the pads 13 may be constructed in the form of bump.

Next, when a molding material for covering the top surface of the semiconductor chip 11 is molded, a plurality of bumps 21 are formed on the top surface of a plate-shaped support wafer 20. The bumps 21 may be formed by a plating method such as an electroplating method or electroless plating method. Alternately, each of the bumps 21 may be formed of a stud bump through a separate bumping process.

Next, the molding material 14 is molded by applying molding resin onto the top surface of the support wafer 20 at a thickness where the bumps 21 are included. Preferably, the molding material 14 is formed of transparent thermosetting resin such as epoxy, polymer, PR or PI.

When the molding material 14 is solidified, a groove 14c is formed in the central portion of the molding material 14. Preferably, the groove 14c is formed by an etching process. When the groove 14c is formed by the etching process, the upper end portions of the bumps 21 formed on the support wafer 20 are exposed from the groove 14c.

Subsequently, the support wafer 20 bonded to the bottom surface of the molding material 14 is removed. Then, the manufacturing of the molding material 14 for covering the top surface of the semiconductor chip 11 is completed.

Next, the molding material 14 having the groove formed therein is closely coupled to the top surface of the semiconductor chip 11. At this time, the molding material 14 is coupled so as to cover the top surface of the semiconductor chip 11 such that the groove 14c faces downward and the ICs 12 and the pads 13 formed on the semiconductor chip 11 are placed in the groove 14c. Accordingly, the groove 14c serves as a cavity 15 formed between the semiconductor chip 11 and the molding material 14.

The pads 13 formed on the semiconductor chip 11 and the bumps 21 formed on the molding material 14 are positioned so as to correspond to each other. When the top surface of the semiconductor chip 14 is covered by the molding material 14, the pads 13 and the bumps 21 are contacted with each other so as to be electrically connected.

In the wafer-level package manufactured through such a process, the lower end of a support portion 14b formed in the outer portion of the molding material 14 is closely attached to the outer portion of the top surface of the semiconductor chip 11 through an adhesive (not shown) coated therebetween.

Further, when the groove 14c of the molding material 14 is formed, the width and depth of the groove 14c are adjusted by an etching process. Therefore, it is possible to adjust the width and depth of the cavity when the molding material is attached to the top surface of the semiconductor chip.

Meanwhile, instead of the groove 14c formed in the central portion of the molding material 14 through an etching process, a damper-shaped wall body 14d may be formed on the outer portion of the molding material 14, as shown in FIG. 13. Accordingly, a groove serving as a cavity 15 is provided in the central portion of the molding material 14.

Further, the lower end of the wall body 14d is closely attached to the top surface of the semiconductor chip 11 through an adhesive, and the pads 13 mounted on the semiconductor chip 11 are directly contacted with the bumps 21 included in the groove 14c. Therefore, it is possible to manufacture the wafer-level package without a separate etching process for forming a groove.

### Third Embodiment

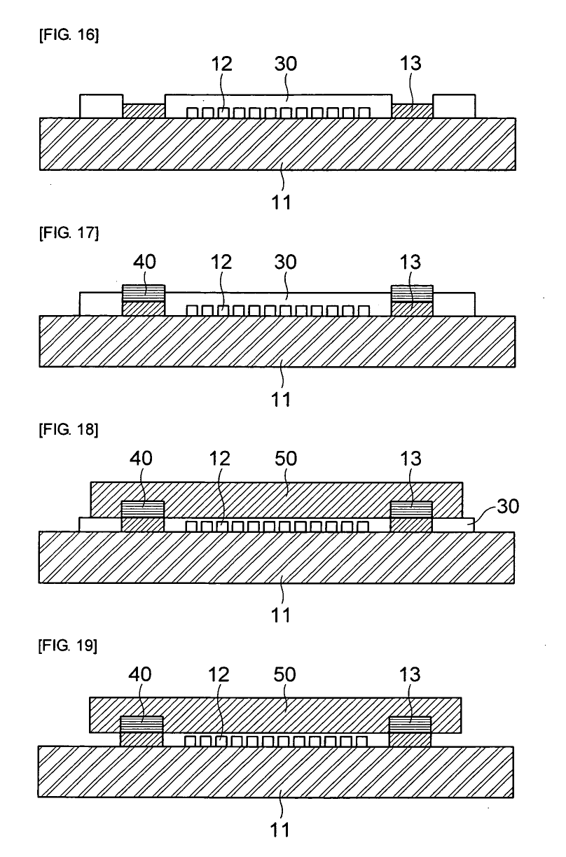

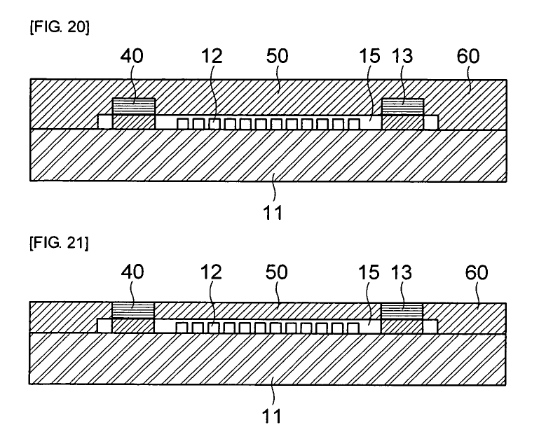

FIGS. 14 to 21 are process diagrams sequentially showing a method of manufacturing a wafer-level package according to a third embodiment of the invention.

First, as shown in FIG. 14, a wafer-level semiconductor chip 11 having a plurality of ICs 12 and pads 13 formed thereon is prepared. The semiconductor chip 11 may be formed of a MEMS element or an IC element, and the plurality of pads 13 are mounted around the ICs 12 formed on the center of the top surface of the semiconductor chip 11.

Here, the pads 13 may be constructed in the form of bump.

Next, a photosensitive layer 30 is formed on the top surface of the semiconductor chip 11 where the ICs 12 and the pads 13 are formed. The photosensitive layer 30 is formed of a dry film resist (DFR) layer using a photoresist layer or dry film which is formed by applying photosensitive resin.

Then, portions of the photosensitive layer 30 are patterned in such a manner that the pads 13 are exposed to the outside. The patterning of the photosensitive layer 30 is performed through an etching process.

Subsequently, a bump 40 with a predetermined height is formed on each top surface of the exposed pads 13. The bump 40 may be formed by a plating method such as an electroplating method or electroless plating method. Alternately, the bump 40 may be formed of a stud bump through a separate bumping process.

Preferably, the bump 40 is formed so as to project from the top surface of the photosensitive layer 30.

Then, a primary molding material 50 is formed on the top surface of the photosensitive layer 30. Preferably, the primary molding material 50 is formed with such a width as to include the ICs 12 and the pads 13 formed on the semiconductor chip 11. That is, when the photosensitive layer 30 under the primary molding material 50 is removed, the width of a cavity should be considered in such a manner that the ICs 12 and the pads 13 can be placed inside the cavity.

Next, the photosensitive layer 30 interposed between the top surface of the semiconductor chip 11 and the primary molding material 50 is removed. The removing of the photosensitive layer 30 can be performed by an ashing process such as drying etching, wet etching, ion injection or the like. As high-pressure etching liquid is jetted between the top surface of the semiconductor layer 11 and the primary molding material 50, only the photosensitive layer 30 can be fused and removed.

Subsequently, a secondary molding material 60 is formed on the outer portion of the top surface of the semiconductor chip 11 so as to be closely attached to the side surface of the primary molding material 50. Then, a cavity 15 is formed under the primary molding material 50. Preferably, the secondary molding material 60 is formed of the same material as the primary molding material 50.

Finally, when the primary and secondary molding materials 50 and 60 are completely solidified, the upper portions of the molding materials 50 and 60 are thinned. At this time, the thinning is performed until the top surface of the bump 40 connected to the pad 13 is exposed.

Preferably, the primary and secondary molding materials 50 and 60 are formed of transparent thermosetting resin such as epoxy, polymer, or PR or PI, as in the first and second embodiments.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

1. A wafer-level package comprising:
a wafer-level semiconductor chip having a plurality of integrated circuits (ICs) and pads formed on the top surface thereof;
a molding material of which the outer portion is supported by the top surface of the semiconductor chip such that a cavity is provided on the semiconductor chip; and
a conducive member filled in a plurality of vias which are formed in arbitrary positions of the molding material so as to pass through the molding material, the conductive member being connected to the pads.

2. The wafer-level package according to claim 1, wherein each of the pads is formed of a bump.

3. The wafer-level package according to claim 1, wherein the conductive member is formed of any one of a wire, a bump, and a conductive filler.

4. The wafer-level package according to claim 1, wherein the vias are formed by a drilling process using a saw or irradiation of laser.

5. The wafer-level package according to claim 4, wherein the vias are formed in positions corresponding to the respective pads formed on the semiconductor chip.

6. The wafer-level package according to claim 3, wherein the conductive member filled in each of the vias is composed of a conductive filler such as metal or conductive polymer.

7. The wafer-level package according to claim 6, wherein the conductive member is formed so as to project from the top surface of the molding material or is formed with the same height as the molding material.

8. The wafer-level package according to claim 1, wherein the molding material is formed of transparent thermosetting resin such as epoxy, polymer, PR (photoresist) or PI (polyimide).

9. The wafer-level package according to claim 1, wherein the outer portion of the molding material is closely fixed to the top surface of the semiconductor chip through an adhesive.

10. A method of manufacturing a wafer-level package, the method comprising:
forming a plurality of ICs and pads on the top surface of a wafer-level semiconductor chip;
molding a molding material having a groove formed in the central portion thereof;
bonding and fixing the molding material to the top surface of the semiconductor chip such that a cavity is formed therebetween;
forming a plurality of vias in arbitrary positions of the molding material; and
filling a conductive filler into each of the vias so as to form a conductive member.

11. The method according to claim 10, wherein the conductive member is formed of any one of a wire, a bump, and a conductive filler.

12. The method according to claim 10, wherein the vias are formed by a drilling process using a saw or irradiation of laser.

13. The method according to claim 11, wherein the vias are formed in positions corresponding to the respective pads formed on the semiconductor chip.

14. The method according to claim 11, wherein the filler filled into the via is composed of a conductive material such as metal or conductive polymer.

15. The method according to claim 10, wherein the molding material is formed of transparent thermosetting resin such as epoxy, polymer, PR or PI.

16. A method of manufacturing a wafer-level package, the method comprising:
forming a plurality of ICs and pads on the top surface of a wafer-level semiconductor chip;
preparing a support wafer;
forming a plurality of bumps in arbitrary positions of the top surface of the support wafer;
molding a molding material such that the bumps formed on the top surface of the support wafer are included;
forming a groove in the central portion of the molding material;
removing the support wafer; and
closely coupling the molding material having the groove to the top surface of the semiconductor chip.

17. The method according to claim 16, wherein the groove is formed by an etching process.

18. The method according to claim 16, wherein when the molding material is closely coupled to the top surface of the semiconductor chip, the groove and the bump exposed from the groove are caused to face the top surface of the semiconductor chip such that the groove serves as a cavity.

19. The method according to claim 18, wherein the molding material is formed of transparent thermosetting resin such as epoxy, polymer, PR or PI.

20. The method according to claim 16, wherein each of the bumps is formed by a plating method such as an electroplating method or electroless plating method or is formed of a stud bump through a bumping process.

21. The method according to claim 20, wherein the bump is formed in a position corresponding to each of the pads formed on the semiconductor chip.

22. The method according to claim 18, wherein the outer portion of the molding material is closely fixed to the top surface of the semiconductor chip through an adhesive.

23. A method of manufacturing a wafer-level package, the method comprising:
forming a plurality of ICs and pads on the top surface of a wafer-level semiconductor chip;
forming a photosensitive layer on the top surface of the semiconductor chip such that the ICs and the pads are covered by the photosensitive layer;
patterning a portion of the photosensitive layer such that the pads are exposed;
forming a plurality of bumps on the top surfaces of the exposed pads;
forming a primary molding material on the top surface of the photosensitive layer such that the bumps are covered;
removing the photosensitive layer such that a cavity is formed around the ICs and the pads;
forming a secondary molding material around the primary molding material; and
thinning upper portions of the primary and secondary molding materials such that the top surfaces of the bumps are exposed.

24. The method according to claim 23, wherein the patterning of the photosensitive layer is performed by an etching process.

25. The method according to claim 24, wherein the photosensitive layer is formed of a photoresist (PR) layer coated with photosensitive liquid or a dry film resist (DFR) layer using a dry film.

26. The method according to claim 25, wherein the photosensitive layer is removed by an ashing process such as a dry or wet etching process or ion injection, or is removed by jetting high-pressure etching liquid to fuse only the photosensitive layer, after the primary molding material is molded.

27. The method according to claim 23, wherein the primary and secondary molding materials formed on the semiconductor chip are formed of transparent thermosetting resin such as epoxy, polymer, PR or PI.

28. The method according to claim 23, wherein each of the bumps is formed by a plating method such as an electroplating method or electroless plating method or is formed of a stud bump through a bumping process.

29. The method according to claim 23, wherein the outer portion of the molding material is closely fixed to the outer portion of the top surface of the semiconductor chip through an adhesive.
